(19) United States
(12) Patent Application Publication
(10) Pub. No.: US 2026/0114084 A1
(43) Pub. Date: Apr. 23, 2026

(54) OPTOELECTRONIC SEMICONDUCTOR DEVICE AND MANUFACTURING METHOD

(71) Applicant: ams-OSRAM International GmbH, Regensburg (DE)

(72) Inventors: Daniel RUHSTORFER, Gmund (DE); Xue WANG, Donaustauf (DE); Alexander BEHRES, Pfatter (DE)

(21) Appl. No.: 19/366,297

(22) Filed: Oct. 22, 2025

(30) Foreign Application Priority Data
Oct. 23, 2024 (DE) 102024130886.9

(51) Int. Cl. H10H 20/824; H10H 20/01; H10H 20/811

(52) U.S. Cl. CPC H10H 20/8242; H10H 20/013; H10H 20/811

(57) ABSTRACT

In at least on embodiment, the optoelectronic semiconductor device comprises a semiconductor layer sequence which has an n-side stack, a p-side stack and an active region between the n-side stack and the p-side stack of a pn-junction, wherein
the n-side stack comprises a second layer being doped with two different n-type dopants, a first one of the n-type dopants has an atomic number of at most 14 and a second one of the n-type dopants is S, Se or Te,
the n-side stack further comprises a first layer being doped with the second one of the n-type dopants, and
the second layer is located between the active region and the first layer.

### CROSS-REFERENCE TO RELATED APPLICATION

This application claims priority to German Patent Application No. 10 2024 130 886.9 filed on Oct. 23, 2024 in the German Patent and Trade Mark Office, the disclosure content of which is hereby incorporated by reference in its entirety.

An optoelectronic semiconductor device is provided. A method for manufacturing such an optoelectronic semiconductor device is also provided.

Document WO 2025/168428 A1 refers to an optoelectronic semiconductor device.

Documents US 2019/0386175 A1 and US 2022/0384680 A1 refer to radiation-emitting semiconductor chips.

A problem to be solved is to provide an optoelectronic semiconductor device that has improved electrical behavior and improved optical output efficiency.

This object is achieved, inter alia, by an optoelectronic semiconductor device and by a method as defined in the independent claims. Exemplary further developments constitute the subject-matter of the dependent claims.

According to at least one embodiment, the optoelectronic semiconductor device comprises a semiconductor layer sequence. The semiconductor layer sequence has an n-side stack and a p-side stack. The n-side stack is n-conductive and the p-side stack is p-conductive. The n-side stack includes a plurality of partial layers. Hence, the n-side stack is a semiconductor layer stack. The different layers of the n-side stack may have different properties, especially concerning their composition and/or their doping profile. Also the p-side stack can be made of a plurality of semiconductor layers, but it is also possible that the p-side stack is of just one semiconductor layer.

The term ‘layer’ may refer to a layer with a specific function and/or physical property. For example, a layer is a continuous region of the semiconductor layer sequence having a same material composition, that is, a same proportion of main constituents of a crystal lattice and/or having a same doping concentration concerning a main dopant, that is, a dopant with the highest concentration. Nonetheless, ramped doping or material composition variation is in principle also possible. Thus, a ‘layer’ could consist of just one homogeneous sub-layer or may consist of a plurality of homogeneous sub-layers.

According to at least one embodiment, the optoelectronic semiconductor device comprises one or a plurality of active regions. The at least one active region is located between the n-side stack and the p-side stack. A growth direction of the semiconductor layer sequence may be a normal of the at least one active region. The at least one active region may be a quantum structure. The term quantum structure comprises in particular any structure in which charge carriers can undergo a quantization of their energy states by confinement. In particular, the term quantum structure does not imply any limitation on the dimensionality of the quantization. It thus includes, among others, quantum wells, quantum wires, quantum rods and quantum dots and any combination of these structures.

For example, the at least one active region is a multi-quantum well, MQW, structure. It is thus possible that the at least one active region includes a plurality of barrier layers with a relatively high bandgap and a plurality of active layers with a relatively low bandgap, the barrier layers and the active layers being arranged in an alternating manner. Radiation is produced in the active region by means of electroluminescence in the intended use of the optoelectronic semiconductor device. The active layers could all be designed for a same emission wavelength or different types of active layers, for example, for different emission wavelength, are combined with each other within the respective active region.

In case of a plurality of active regions, the active regions could be provided in a stack with tunnel junctions between adjacent ones of the active regions. The active regions could be of a same design, for example, could be configured for emitting radiation of a same wavelength, or could be of different designs, for example, to emit different wavelengths.

For example, the active region starts at a beginning of a first quantum structure that produces radiation. This may refer to an intended use of the optoelectronic semiconductor device and/or to an intended emission wavelength of the optoelectronic semiconductor device. The first quantum structure may especially be the first quantum structure seen from the n-side layer stack. In case the semiconductor layer sequence comprises both radiative and non-radiative quantum structures, the first quantum structure is the first one of the radiative ones, coming from the n-side stack. For example, the radiative quantum structures have a smaller band gap than the non-radiative ones.

Alternatively or additionally, the active region may start where a drop of the Al/(Al+Ga) ratio begins to start. For example, before and after the active region the semiconductor layer sequence has a first ratio Al₁ and a second ratio Al₂, respectively; further, the active region has a minimum ratio Alₘᵢₙ; then the point of start of the active region may be where 10% of the resulting drop occurs, that is, at the following ratio Alstart:

$${Al}_{start} = {Al}_{min} + 0.9 ( \frac{{Al}_{1} + {Al}_{2}}{2} - {Al}_{min} )$$

For example,

$$\frac{{Al}_{1} + {Al}_{2}}{2} - {Al}_{min} \geq 0.05 or \frac{{Al}_{1} + {Al}_{2}}{2} - {Al}_{min} \geq 0.10 .$$

This may especially apply if the semiconductor material is expressed as Alₖ₁Inₖ₂Ga₁₋ₖ₁₋ₖ₂(As, P), with k1+k2≤1, k1>0, k2≥0.

According to at least one embodiment, the n-side stack comprises a second layer which is, for example, an n-junction layer. The second layer is located in proximity of the active region. For example, a distance along the growth direction between the second layer and the closest active layer is at most 1000 nm or is at most 300 nm or is at most 100 nm.

In case the second layer is the n-junction layer, this may refer to a section of the semiconductor body where most of the space-charge-region on the n-side of a pn-junction is located. It is typically the layer or layer sequence closest to the active region on the n-side of the pn-junction which has an average doping density of, for example, more than 1×10¹⁷ cm⁻³.

According to at least one embodiment, the second layer is doped with two or more than two different dopants, like n-type dopants. A first one of the n-type dopants has an atomic number of at most 14, like Si. A second one of the n-type dopants is S, Se, Te. For example, it is possible that there are no further n-type dopants in the second layer.

It is possible that the second layer includes a third dopant and even a fourth dopant and possibly a fifth dopant, and so on. However, the predominant doping is the first one of the n-type dopants and the second most important dopant may be the second one of the n-type dopants. Especially, a cumulative doping concentration of all other dopants, in addition to the first one and the second one of the n-type dopants, may amount to at most 10% or at most 1% or at most 0.1% of the cumulative doping concentration of the first and second one of the n-type dopants. Moreover, the doping concentration of the first one of the dopants is at least as high as the doping concentration of the second one of the dopants or exceeds the latter by at least a factor of two or by at least a factor of five or by at least a factor of ten, especially at a side of the second layer remote from the first layer. In other words, the second layer is only or predominantly doped with the first one of the n-type dopants.

According to at least one embodiment, the n-side stack further comprises a first layer, like a current spreading layer, a cladding layer and/or a contact layer. The first layer is doped with the second one of the n-type dopants, in particular the second one may be the only n-type dopant present in the first layer. Hence, the only n-type dopant of the first layer may be the second one of the n-type dopants. Being doped with the second one of the n-type dopants only may mean that a concentration of all other n-type dopants together is at most 3×10¹⁸ cm⁻³ or is at most 1×10¹⁸ cm⁻³ or is at most 5×10¹⁷ cm⁻³ or is at most 1×10¹⁷ cm⁻³ or is at most 2×10¹⁶ cm⁻³.

For example, in the first layer the doping concentration of the second one of the n-type dopants is at least as high as the doping concentration of the first one of the n-type dopants, or a cumulative doping concentration of all dopants but the second one of the n-type dopants together, or exceeds it by at least a factor of two or by at least a factor of five or by at least a factor of ten or by at least a factor of 20 or by at least a factor of 100. Thus, the predominant dopant of the first layer is in any case the second one of the n-type dopants. In other words, the first layer is only or predominantly doped with the second one of the n-type dopants.

According to at least one embodiment, the second layer is located between the active region and the first layer. It is possible that the second layer directly adjoins the first layer. Further, it is also possible that the second layer directly adjoins the active region but there may also be further layers of the n-side stack between the second layer and the active region.

According to at least one embodiment, the second layer has a higher Al/(Al+Ga) ratio than the first layer. For example, if the first layer is of Alₓ₁Gaₓ₂In₁₋ₓ₁₋ₓ₂ (As, P) and the second layer is of Al_{y1}Ga_{y2}In_{1-y1-y2}(As, P), with x1+x2≤1, y1+y2≤1, x1>0, y1>0, x2≥0 and y2≥0, and if Q1=x1/(x1+x2) and Q2=y1/(y1+y2), then Q2−Q1≥0.05 or Q2−Q1≥0.10 or Q2−Q1≥0.20. Alternatively or additionally, Q2/Q1≥1.3 or Q2/Q1≥1.6 or Q2/Q1≥2.0 or x1/y1≥2.5.

This may be true in particular for infrared-emitting devices. For devices emitting in the visible spectral range, 01=02 may apply, for example, within manufacturing tolerances, like at most ±0.03 or at most ±0.01.

In at least one embodiment, the optoelectronic semiconductor device comprises a semiconductor layer sequence which has an n-side stack, a p-side stack and an active region between the n-side stack and the p-side stack of, for example, a pn-junction, wherein
the n-side stack comprises a second layer, like an n-junction layer, containing two different n-type dopants, a first one of the n-type dopants has an atomic number of at most 14 and a second one of the n-type dopants is S, Se or Te,
the n-side stack further comprises a first layer, like a current spreading layer, being doped with the second one of the n-type dopants, especially only or predominantly, and
the second layer is located between the active region and the first layer.

Tellurium-doping is used as donors on the n-side, for example in an n-current spreading layer and/or in an n-contact layer in order to realize high doping levels and to achieve high conductivity or low contact-resistance, for example. Especially for phosphorus containing layers, Te is known as surfactant which remains on the growth surface after switching off the Te source during epitaxial growth. This surface accumulation leads to Te segregation and an extended unintentional and diffuse Tellurium doping profile which is hard to control. This so-called segregation of Te as a dopant can affect also the active region where it can act as a crystal defect, hindering efficient light generation. The optoelectronic semiconductor device comprises or is, for example, a light-emitting diode, LED for short. One possibility to overcome this issue is to place at least one extra nominally lowly doped spacer layer between the active region and the Te-doped layer to deal with this phenomenon. Especially in As containing layers, Te doping can cause the formation of Te clusters which in close proximity to the active region cause electrooptical degradation. Here an insertion of an additional not Te-doped layer between the Te-doped layer and the active region increases the distance between the Te clusters and the active region and therefore reduces the corresponding degradation effects.

For example, the spacer layer has a thickness of at least 10 nm or of at least 50 nm and/or of at most 800 nm or of at most 400 nm.

For example, in AlGaInAsP-based LEDs, only one type of n-dopant is being used to define the n-side of a pn-junction: either Si-doping or Te-doping, for example. Both dopants have their own issues:
1) When using only Te, the extra nominally lowly doped spacer material needs to be grown just before the active region specifically to accommodate the segregation induced doping profile which forms due to the surfactant properties of Tellurium. Some amount of Te-doping also has the advantage of suppressing an ordering phenomenon in III-V random alloys.
2) When using only Si, doping profiles can be defined much more sharply as it is not a surfactant, however, there are limitations to the achievable carrier density and mobility, and therefore the conductivity is limited due to the amphoteric nature of the incorporation of Si-dopants as both donors and acceptors simultaneously. There is also the risk of inducing ordered alloys when using Si only.

In the optoelectronic semiconductor device described herein, the advantages of Si-doping and Te-doping are combined by choosing the dopant with more appropriate properties in different parts of one design of the semiconductor layer sequence.

Thus, in the optoelectronic semiconductor device described herein, Group VI-doping is used in the layers of the n-side stack where low resistivity and therefore high carrier density and mobility is required, that is, in particular the n-current spreading layer and an n-contact layer, but Si-doping is used to define the second layer of the pn-junction before growing the layers of the active region.

This second layer can be an AlGaInP:Si layer with an Al/(Al+Ga) ratio of 0.8 to 1 with simultaneous decay of the Te background doping due to segregation of surface accumulation. That means that the slow Te-decay starts much more distant from the active region and happens simultaneously during the growth of the Si-doped layers. Since the Si-decay is much faster than the Te-decay, it can start later. This scheme allows to shut down the Te-supply much earlier during epitaxial growth, making it possible to remove much of the spacer layers which are otherwise needed to keep the doping density, that is, the impurity density, in the active region sufficiently low. This is because there is the possibility to define the doping profile very sharply when supplying Si as there is basically no surfactant effect and thus almost no segregation with that dopant. The remaining Te background can be balanced in such a way that there is enough doping to suppress ordering phenomena, but it is low enough at the same time not to affect the active region negatively.

The possibility to decrease the spacer layer thickness leads to reduced costs by lower process time and lower material consumption. The decreased layer thickness also reduces absorption and decreases series resistance, leading to higher brightness and lower forward voltage, overall contributing to an increased wall plug efficiency.

Also, with this doping design there is less lowly doped material between the active region and the second layer which increases the hole confinement in the active region and thus further improves efficiency, in particular when operating devices at elevated temperatures. It is further possible to keep Te further away from the active region which leads to reduced degradation in IR-emitting LEDs based on AlGaInAs.

According to at least one embodiment, the semiconductor layer sequence is of the AlInGaAsP material system. That is, the semiconductor layer sequence is based on the III-V compound semiconductor material AlₙGaₘIn₁₋ₙ₋ₘAsₖP₁₋ₖ, wherein 0≤n≤1, 0≤m≤1, n+m≤1 and 0≤k≤1 applies, especially for each layer of the semiconductor layer sequence. The semiconductor layer sequence may comprise dopants and additional constituents. For simplicity's sake, however, only the essential constituents of the crystal lattice of the semiconductor layer sequence are indicated, that is, Al, As, Ga, In or P, even if these may in part be replaced and/or supplemented by small quantities of further substances.

According to at least one embodiment, the first one of the n-type dopants is Si and the second one of the n-type dopants is Te.

According to at least one embodiment, the n-side stack is electrically next to an electric n-contact and the p-side stack is electrically next to an electric p-contact. For example, the electric n-contact and/or the electric p-contact are of Ohmic conductance and, thus, may be metallic contacts or contacts of a transparent conductive oxide, TCO for short. For example, the electric n-contact is in direct electric contact with the n-side stack and the electric p-contact is in direct electric contact with the p-side stack. It is possible that, for example, the electric n-contact terminates in the n-side stack after running through the at least one active region while being electrically separated, like electrically insulated, from all of the semiconductor layer sequence but the n-side stack.

According to at least one embodiment, a peak doping concentration of the first one of the n-type dopants in the second layer is at least 5×10¹⁶ cm⁻³ or is at least 1×10¹⁷ cm⁻³ or is at least 3×10¹⁷ cm⁻³. Alternatively or additionally, said peak doping concentration of the first one of the n-type dopants in the second layer is at most 6×10¹⁸ cm⁻³ or is at most 3×10¹⁸ cm⁻³.

According to at least one embodiment, a local doping concentration of the first one of the n-type dopants in the second layer is at least 0.6 times or is at least 0.7 times or is at least 0.8 times the peak doping concentration of the first one of the n-type dopants in the second layer. This may apply throughout the second layer. In other words, the doping concentration of the first one of the n-type dopants may be constant in the second layer.

According to at least one embodiment, the first one of the n-type dopants in the second layer is applied with an interval doping and/or a ramped doping. In case of an interval doping, regions with relatively high concentrations of the first one of the n-type dopants alternate with regions with relatively low concentrations of the first one of the n-type dopants. For example, the difference in the doping concentration between these regions is at least a factor of two or at least a factor of ten or at least a factor of 10² and/or at most a factor of 10⁵ or at most a factor of 10⁴. In case of ramped doping, the doping concentration of the first one of the n-type dopants changes continuously, like linearly or almost linearly. The ramp in the doping profile could rise towards the active region and/or could fall towards the active region. Mixtures of interval doping and ramped doping are possible, also with varying interval lengths of the interval doping and with different slopes of possibly a plurality of ramps in case of ramped doping being present.

According to at least one embodiment, a thickness of the second layer is at least 20 nm or is at least 50 nm or is at least 100 nm. Alternatively or additionally, this thickness is at most 1000 nm or is at most 600 nm or is at most 300 nm.

According to at least one embodiment, a doping concentration of the second one of the n-type dopants decays by at least a factor of three or by at least a factor of five or by at least a factor of ten over the second layer and towards the active region. For example, especially in the case of InGaAlP, said factor is at most 10⁵ or is at most 10⁴. In other words, said factor is a quotient of the local doping concentration of the second one of the n-type dopants at the end of the first layer and at the beginning of the active region, seen along the growth direction. This may especially apply for optoelectronic semiconductor devices emitting visible light. For IR-emitting optoelectronic semiconductor devices, the decay of Te in the second layer may occur on much smaller length, seen along the growth direction, so that in case of IR-emitters Te may be present in the second layer only in a subregion next to the first layer.

According to at least one embodiment, in and/or at the active region the doping concentration of the second one of the n-type dopants is at most 1×10¹⁸ cm⁻³ or is at most 5×10¹⁷ cm⁻³ or is at most 1×10¹⁷ cm⁻³ or is at most 5×10¹⁶ cm⁻³. Hence, compared with the doping concentration of the second one of the n-type dopants in the first layer, said doping concentration has decayed quite a lot until the active region.

It is possible that the doping concentration of the second one of the n-type dopants monotonically or strictly monotonically decreases towards the active region. For example, along the growth direction, for each z between the first layer and the active region it applies for the doping concentration C2 of the second one of the n-type dopants: C2(z)≥C2(z+dz) or C2(z)>C2(z+dz) wherein dz is a length >0 and z increases along the growth direction. This may apply to an actual curve or a fitted curve of measurement data as measurement data comprises some degree of noise.

According to at least one embodiment, a peak doping concentration of the second one of the n-type dopants in the first layer is at least 1×10¹⁷ cm⁻³ or is at least 5×10¹⁷ cm⁻³ or is at least 1×10¹⁸ cm⁻³. Alternatively or additionally, said peak doping concentration is at most 6×10²⁰ cm⁻³ or 5×10¹⁹ cm⁻³ or is at most 6×10¹⁸ cm⁻³.

It is possible that the peak doping concentration of the second one of the n-type dopants in the first layer exceeds the peak doping concentration of the first one of the n-type dopants in the second layer, for example, by at least a factor of 1.5 or by at least a factor of two and/or by at most a factor of 100 or by at most a factor of 30 or by at most a factor of ten. This applies, for example, for optoelectronic semiconductor devices emitting visible light.

In case of optoelectronic semiconductor devices emitting IR radiation, the peak doping concentration of the second one of the n-type dopants in the first layer may be equal to or may be lower than the peak doping concentration of the first one of the n-type dopants in the second layer, for example, by at least a factor of 1.2 or by at least a factor of 1.6 or by at least a factor of two and/or by at most a factor of 20 or by at most a factor of ten or by at most a factor of five.

According to at least one embodiment, a local doping concentration of the second one of the n-type dopants in the first layer is at least 0.6 times or is at least 0.7 times or is at least 0.8 times the peak doping concentration of the second one of the n-type dopants in the first layer. This may apply throughout the first layer. In other words, the doping concentration of the second one of the n-type dopants may optionally be constant in the first layer.

Alternatively, there may be an interval doping and/or a ramped doping of the second one of the n-type dopants in the first layer, analogously to what is possible for the first one of the n-type dopants in the second layer.

According to at least one embodiment, a thickness of the first layer is at least 25 nm or is at least 100 nm or is at least 200 nm. Alternatively or additionally, this thickness is at most 4 μm or is at most 2 μm or is at most 1 μm or is at most 500 nm.

According to at least one embodiment, the n-side stack further comprises a dopant segregation layer. For example, the dopant segregation layer is directly at the active region and/or is directly at the second layer.

According to at least one embodiment, an average or maximum doping concentration, especially an average or maximum n-doping concentration, in the dopant segregation layer is at most 1×10¹⁸ cm⁻³ or is at most 5×10¹⁷ cm⁻³ or is at most 2×10¹⁷ cm⁻³ or is at most 1×10¹⁷ cm⁻³ or is at most 5×10¹⁶ cm⁻³. Hence, it is possible that the segregation layer may be partially, or alternatively completely, an intrinsic layer without significant doping.

It is possible that the segregation layer is composed of a plurality of sublayers. Such sublayers could include unintentionally doped layers and/or at least one ramp layer and/or a non-radiative quantum structure, for example.

For example, in the ramp layer the Al content is decreased towards the active region, for example, linearly or exponentially decreasing as a function of distance from the second layer. For example, the ramp layer has a thickness of at most 200 nm or of at most 100 nm or of at most 50 nm and/or of at least 10 nm or of at least 20 nm or of at least 30 nm.

Otherwise, it is possible that the Al content is constant throughout the segregation layer. For example, if the segregation layer is of Al_{z1}In_{z2}Ga_{1-z1-z2}A(As, P), with z1+z2≤1, z1>0, z2≥0, then z1 is constant, especially within manufacturing tolerances, like at most ±0.05 or at most ±0.03 or at most ±0.01. The same may analogously apply for x1 and/or y1 throughout the first layer and/or the second layer.

According to at least one embodiment, an average or maximum doping concentration of the first one of the n-dopants in the segregation layer is at most 1×10¹⁷ cm⁻³ or is at most 3×10¹⁶ cm⁻³ or is at most 1×10¹⁶ cm⁻³ and an average or maximum doping concentration of the second one of the n-type dopants is at least 3×10¹⁶ cm⁻³ or is at least 5×10¹⁶ cm⁻³ and at most 1×10¹⁸ cm⁻³ or at most 5×10¹⁷ cm⁻³ or at most 2×10¹⁷ cm⁻³ or at most 1×10¹⁷ cm⁻³. Hence, in the segregation layer the local and/or the average or maximum doping concentration of the first one of the n-dopants can be less than the local and/or average or maximum doping concentration of the second one of the n-dopants. This may apply throughout the segregation layer.

According to at least one embodiment, a thickness of the segregation layer is at least 5 nm or is at least 10 nm or is at least 20 nm. Alternatively or additionally, said thickness is at most 500 nm or is at most 300 nm or is at most 100 nm.

According to at least one embodiment, the n-side stack further comprises a roughening layer at a side of the first layer remote from the active region. It is possible that the roughening layer comprises a roughening for improving an outcoupling efficiency for radiation produced in the active region.

According to at least one embodiment, the roughening layer is doped with the second one of the n-type dopants only or predominantly. Hence, the roughening layer may be free of the first one of the n-type dopants.

According to at least one embodiment, the optoelectronic semiconductor device comprises or is a light-emitting diode for emitting incoherent radiation. Otherwise, the optoelectronic semiconductor device may also be a laser.

Especially, the optoelectronic semiconductor device is a micro-LED or comprises a micro-LED or a micro-LED array. As a broad definition, a micro-LED could be seen as any light emitting diode, LED, generally not a laser, with a particularly small size. For example, a growth substrate is removed from micro-LEDs, so that typical heights of such micro-LEDs are in the range of 1 μm to 10 μm, for example.

In principle, a micro-LED does not necessarily have to have a rectangular radiation emission surface. Generally, for example, an LED could have a radiation emission surface in which, in plan view of the layers of the layer stack, any lateral extent of the radiation emission surface is less than or equal to 100 μm or less than or equal to 70 μm. For example, in the case of rectangular micro-LEDs, an edge length, especially in plan view of the layers of the layer stack, smaller than or equal to 70 μm or smaller than or equal to 50 μm may be a criterion. Mostly, such micro-LEDs are provided on wafers with—for the μLED non-destructively—detachable holding structures.

At present, micro-LEDs are mainly used in displays. The micro-LEDs form pixels or subpixels and emit light of a defined color. Small pixel size and a high density with close distances make micro-LEDs suitable, among others, for small monolithic displays for augmented reality, AR, applications, especially data glasses. In addition, other applications are being developed, in particular regarding the use in data communication or pixelated lighting applications.

Different ways of spelling micro-LED, like μLED, μ-LED, μLED, u-LED or micro light emitting diode can be found in the relevant literature.

According to at least one embodiment, a peak wavelength emitted by the optoelectronic semiconductor device in intended operation is at least 565 nm or is at least 590 nm or is at least 610 nm. Alternatively or additionally, said peak wavelength is at most 790 nm or is at most 750 nm or is at most 680 nm.

According to at least one embodiment, a peak wavelength emitted by the optoelectronic semiconductor device in intended operation is more than 790 nm or is at least 820 nm or is at least 920 nm. Alternatively or additionally, said peak wavelength is at most 1.1 μm or is at most 1060 nm or is at most 980 nm.

A method for manufacturing the optoelectronic semiconductor device is additionally provided. By means of the method, an optoelectronic semiconductor device is produced as indicated in connection with at least one of the above-stated embodiments. Features of the optoelectronic semiconductor device are therefore also disclosed for the method and vice versa.

In at least one embodiment, the method is for producing an optoelectronic semiconductor device. The method includes producing the n-side stack of the semiconductor layer sequence which comprises the following steps, especially in the order given:
growing the first layer and providing only or predominantly the second one of the n-type dopants during growth of the first layer, and
growing the second layer which may be the n-junction layer directly on the first layer and providing only or predominantly the first one of the n-type dopants during growth of the second layer.

Concerning the terms ‘only’ and ‘predominantly’, reference is made to the corresponding explanations on the optoelectronic semiconductor device above.

Hence, the second one of the n-type dopants is provided during growth of the first layer but not or not significantly during growth of the second layer, and during growth of the second layer only the first one of the n-type dopants is provided. It is possible that the first one of the n-type dopants is provided exclusively during the growth of the second layer and not during growth of any other layer of semiconductor layer sequence.

The method may further include the steps of growing the overall semiconductor layer sequence on a growth substrate, removing the growth substrate, etching the semiconductor layer sequence to produce a roughening for extracting radiation and to provide electrical contacts. However, as emphasis lays on the second layer and the first layer, only the growth of the latter layers is referred to in some detail.

For example, the optoelectronic semiconductor device is a luminaire for horticulture.

An optoelectronic semiconductor device and a method described herein are explained in greater detail below by way of exemplary embodiments with reference to the drawings. Elements which are the same in the individual figures are indicated with the same reference numerals. The relationships between the elements are not shown to scale, however, but rather individual elements may be shown exaggeratedly large to assist in understanding.

In the figures:

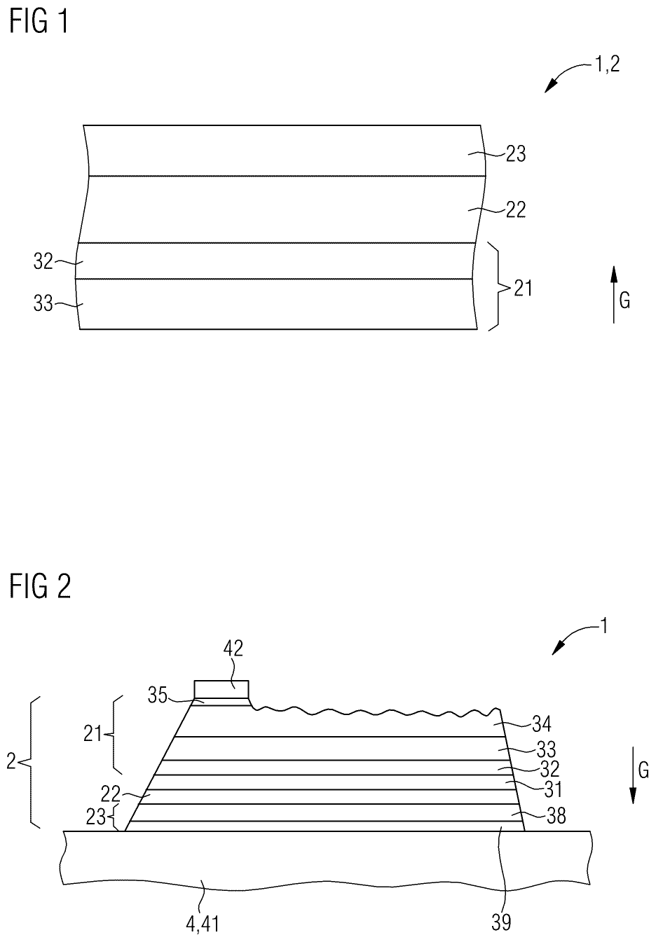

FIGS. 1 to 3 are schematic sectional views of exemplary embodiments of optoelectronic semiconductor devices described herein,

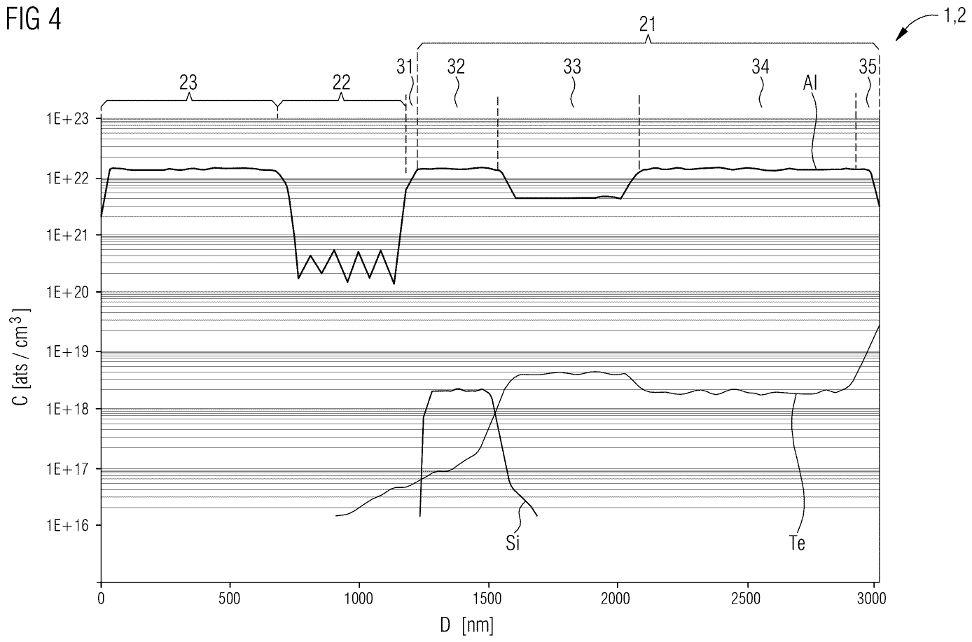

FIG. 4 is a schematic representation of a secondary-ion mass spectrometry measurement of an exemplary embodiment of an optoelectronic semiconductor device described herein,

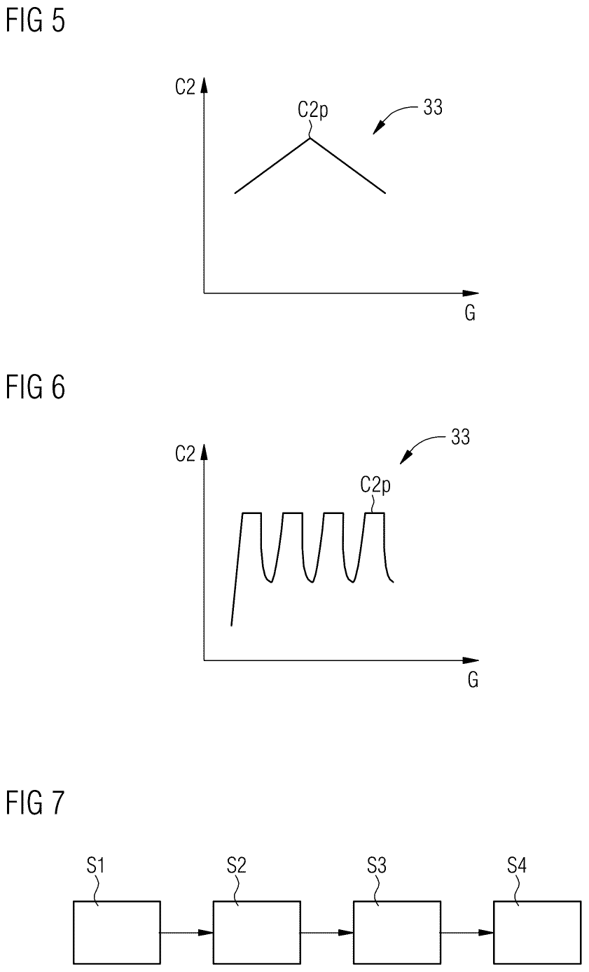

FIGS. 5 and 6 are schematic representations of doping profiles in first layers of exemplary embodiments of optoelectronic semiconductor devices described herein,

FIG. 7 is a schematic block diagram of an exemplary embodiment of a manufacturing method for optoelectronic semiconductor devices described herein,

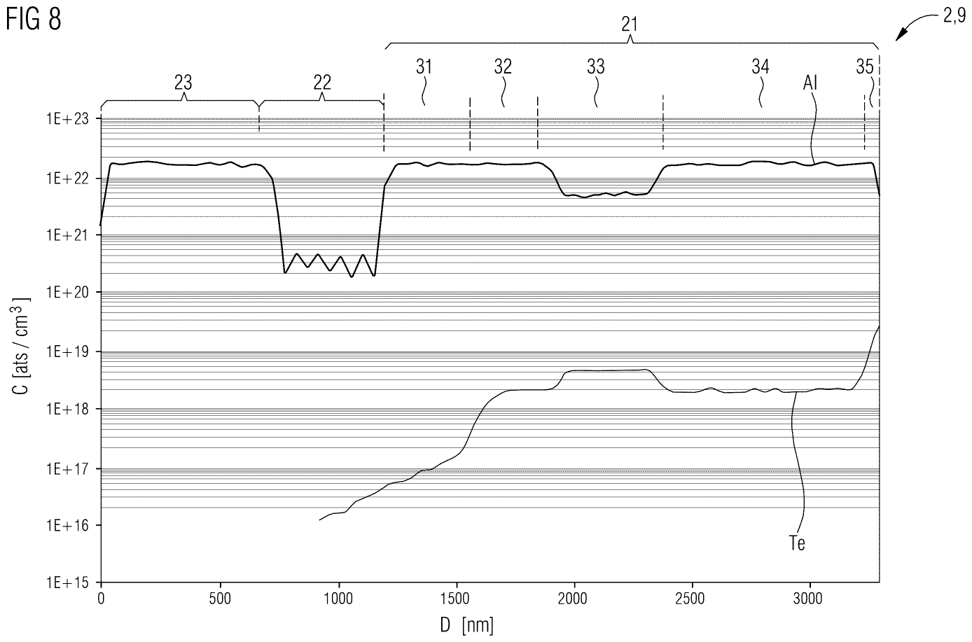

FIG. 8 is a schematic representation of a secondary-ion mass spectrometry measurement of a modified optoelectronic semiconductor device, and

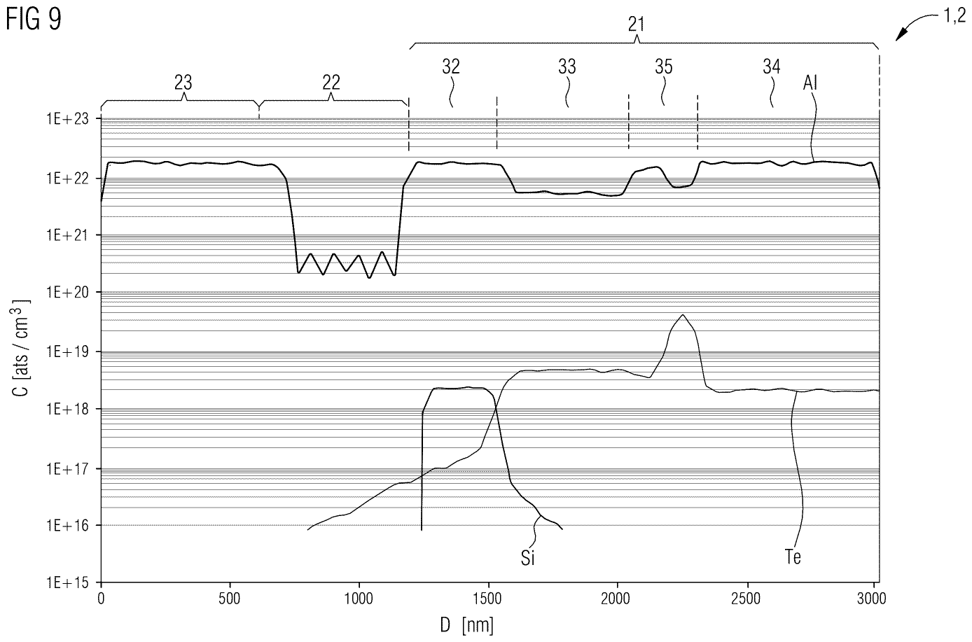

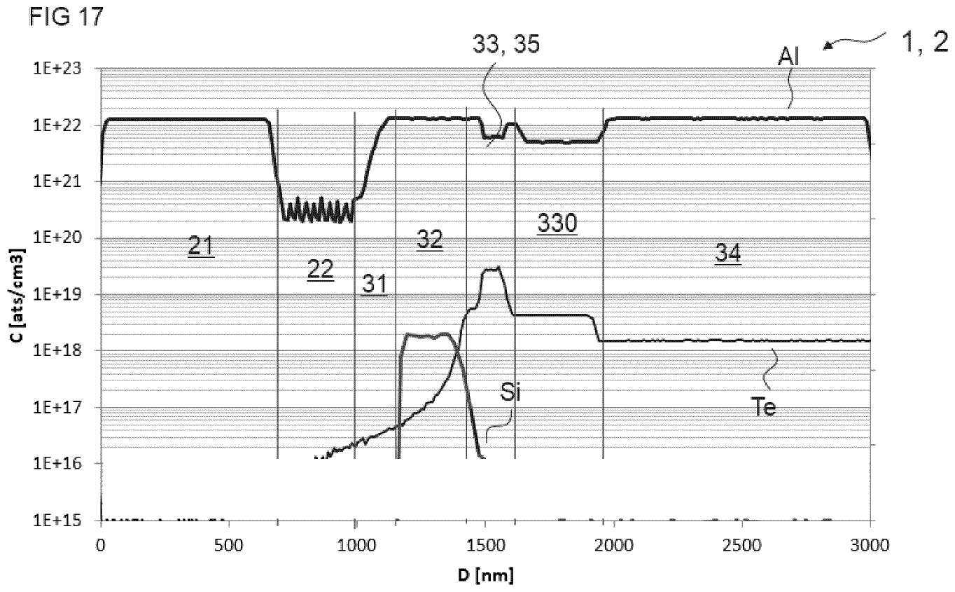

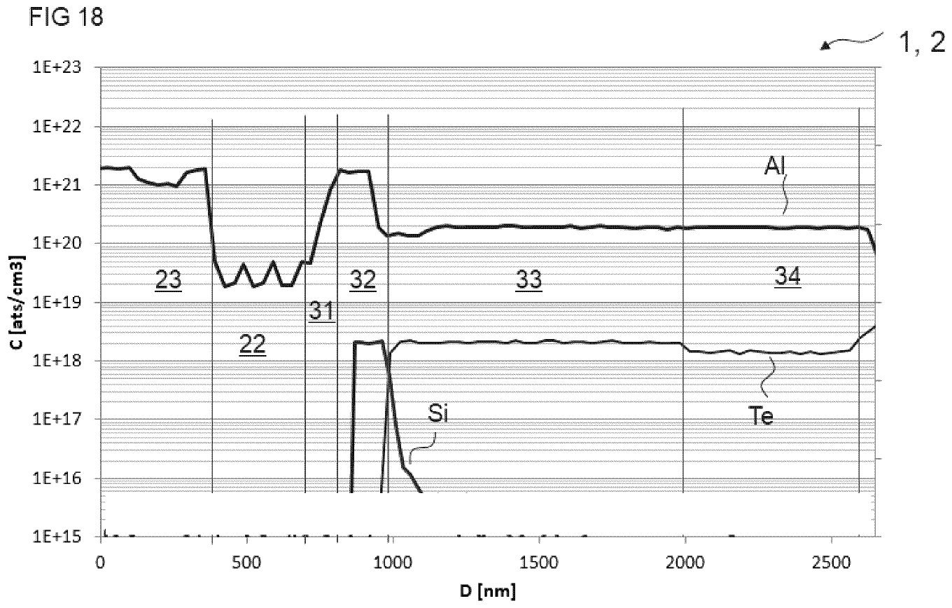

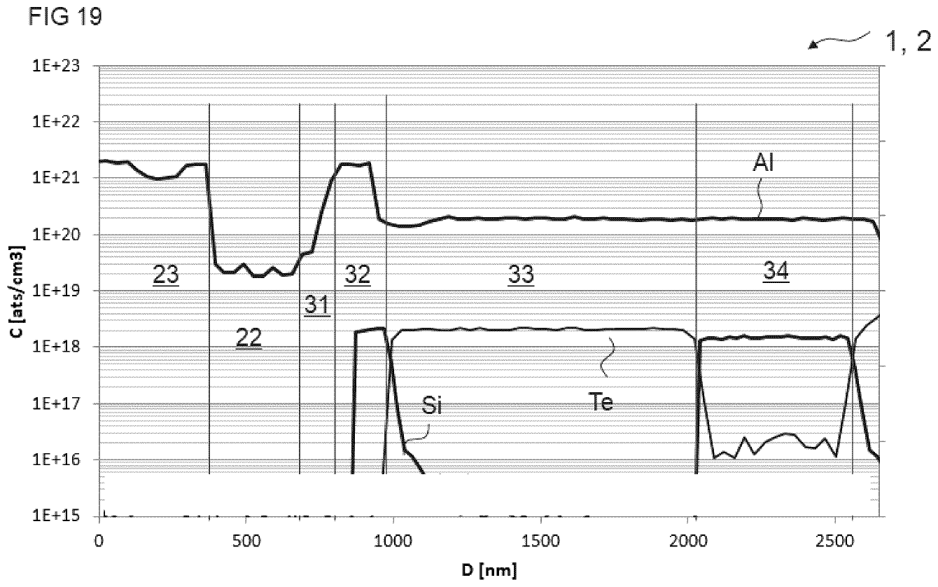

FIGS. 9 to 20 are schematic representations of secondary-ion mass spectrometry measurements of exemplary embodiments of optoelectronic semiconductor devices described herein.

FIG. 1 illustrates an exemplary embodiment of an optoelectronic semiconductor device 1. The optoelectronic semiconductor device 1 comprises a semiconductor layer sequence 2 based on GaAlInP or also on InAlGaAs depending on the desired emission wavelength. The semiconductor layer sequence 2 comprises an n-side stack 21, a p-side stack 23 and an active region 22 between the n-side stack 21 and the p-side stack 23. The active region 22 is grown on the n-side stack 21 so that a growth direction G of the semiconductor layer sequence 2 runs from the n-side stack 21 towards the p-side stack 23. The active region 22 is a MQW structure, for example, and may be configured to produce red light.

The n-side stack 21 includes a first layer 33, like a current spreading layer which is followed along the growth direction G directly by a second layer 32, which is, for example, an n-junction layer. The second layer 32 may be next to the active region 22. Moreover, the n-side stack 21 is doped with two different n-type dopants.

The first-grown first layer 33 is doped with a second one of the n-type dopants only. The second dopant is, for example, Te, Se or S. The second dopant extends into the second-grown second layer 32, however, the second layer 32 is predominantly doped with a first one of the n-type dopants. The first dopant is Si, for example.

As mentioned above, the semiconductor layer sequence is based on the AlGaInP material system. For example, the In proportion is adjusted such that the crystal lattice is close to lattice matching with GaAs, while the Al/Ga ratio may be tuned freely.

In FIG. 2, another example of the optoelectronic semiconductor device 1 is shown. In this example, the semiconductor layer sequence 2 is placed on a carrier 4 which is different from a growth substrate of the semiconductor layer sequence 2. Thus, the p-side stack 23 is next to the carrier 4. The semiconductor layer sequence 2 may be attached to the carrier 4 by means of soldering, for example. It is possible that the semiconductor layer sequence 2 narrows in a direction away from the carrier 4. Thus, it is possible that the semiconductor layer sequence 2 has the shape of a truncated pyramid.

The semiconductor layer sequence 2 as shown in FIG. 2 may constitute a pixel of the optoelectronic semiconductor device 1. Optionally, there is a plurality of such pixels so that the optoelectronic semiconductor device 1 could include an array of light-emitting units which are, for example, produced from the semiconductor layer sequence 2 by etching.

Optionally, the p-side stack 23 includes a p-contact layer 39 next to the carrier 4 and a p-junction layer 38 next to the active region 22. For example, the p-contact layer 39 is heavily p-doped and the thicker p-junction layer 38 is only moderately p-doped.

Further optionally, the n-side stack 21 may include a segregation layer 31 which can be located directly between the active region 22 and the second layer 32. The segregation layer 31 may nominally be undoped, that is, during growth of the segregation layer 31 no dopant may be provided. However, as the segregation layer 31 may still be n-conductive because of being grown after the first layer 33, for example, the segregation layer 31 may be n-conductive and may thus be regarded as being part of the n-side stack 21.

In addition, the semiconductor layer sequence 2 could include a roughening layer 34 at a side of the first layer 33 remote from the active region 22. The roughening layer 34 can be provided with a roughening for improved coupling out of light produced in the active region 22 during operation of the optoelectronic semiconductor device 1.

Along the growth direction G, the roughening layer 34, if present, or the first layer 33 may optionally be preceded by an n-contact layer 35. If there is the roughening, it is possible that the n-contact layer 35 is present only at one or a plurality of relatively small portions on a side of the semiconductor layer sequence 2 remote from the carrier 4.

The semiconductor layer sequence 2 and the corresponding pixel can electrically be contacted by means of the carrier 4 which can thus include an electric p-contact 41. At the n-contact layer 35, an electric n-contact 42 can be applied. The electric contacts 41, 42 may be metallic contacts. Further, there can be metallic, dielectric and/or totally reflecting mirror elements for improved efficiency, not shown.

Other than shown in FIG. 2, it is possible that the n-contact layer 35 is a continuous, hole-free layer directly between the second layer 33 and the roughening layer 34. In this case, the contact layer 33 is locally exposed from the roughening layer 34 where the electric n-contact 42 layer is placed. This variant as well as the variant shown in FIG. 2 is possible in all examples of the optoelectronic semiconductor device 1.

Side faces of the semiconductor layer sequence 2 may be provided with at least one passivation layer, not shown.

For further details on the semiconductor layer sequence 2 and on the electric contacting, see also documents US 2019/0386175 A1 and US 2022/0384680 A1, the disclosure content of which is hereby incorporated by reference.

Otherwise, the same as to FIG. 1 may also apply to FIG. 2, and vice versa.

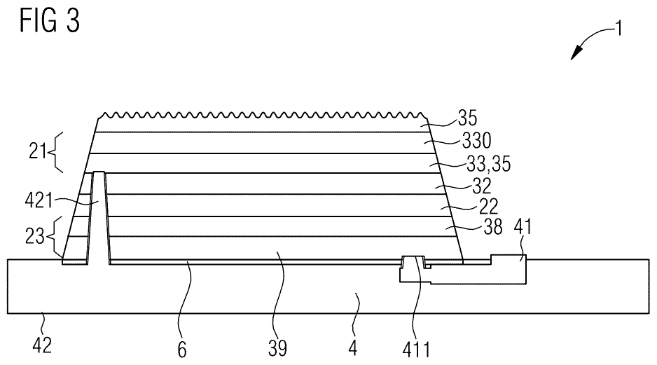

In FIG. 3, a further electric contact scheme is illustrated that could also apply to all examples of the optoelectronic semiconductor device 1. In this case, the semiconductor layer sequence 2 is electrically contacted from one single side via the carrier 4. The electric contacts 41, 42 include through-contacts 411, 421 which run though a mirror 6 between the semiconductor layer sequence 2 and the carrier 4. The electric p-contact 41 is arranged on the carrier 4 but is electrically insulated from remaining portions of the carrier 4. Further, the electric n-through-contact 421 runs through the active region 22 into the first layer 33 which is in this case at the same time the n-contact layer 35. In a lateral direction, the through-contact 421 is electrically insulated from the semiconductor layer sequence so that the through-contact 421 is in direct electric contact only with the first layer 33 and the carrier 4 that itself serves as the electric n-contact 42. A further layer 330 serves in this configuration as the current spreading layer. Hence, the second layer 32 configured as, for example, the n-junction layer is directly followed by the first layer 33 which is the n-contact layer being directly followed by the current spreading layer 330.

Otherwise, the same as to FIGS. 1 and 2 may also apply to FIG. 3, and vice versa.

In FIG. 4, a secondary-ion mass spectrometry, SIMS, measurement of an exemplary embodiment of the optoelectronic semiconductor device 1 is shown. The measurement may be done along a depth D direction, hence along the direction D which is anti-parallel to the growth direction G there may occur some fading-out. Illustrated are the concentrations of Al, Si and Te as measured. The optoelectronic semiconductor device 1 is based on GaAlInP and is configured to emit visible light.

The semiconductor layer sequence 2 may be grown on a growth substrate which is, for example, of GaAs, not shown. Directly at the growth substrate, there can optionally be a buffer layer on which the contact layer 35 is grown; in FIG. 4 the buffer layer is not shown. The contact layer 35 is followed by the roughening layer 34. The buffer layer and the growth substrate may not be present in the finished optoelectronic semiconductor device 1. The layers 37, 35, 34 are part of the n-side stack 21 and can all be doped with Te with different doping concentrations. In the respective layers, the doping concentrations may approximately and/or nominally be constant.

Next, there is the first layer 33 configured as, for example, the current spreading layer. This first layer 33 has in this example a thickness of around 500 nm and is nominally of AlInP doped with Te only with a concentration of about 4×10¹⁸ cm⁻³. The presence of Si in the first layer 33 may be considered as being an artifact along the depth D direction stemming from the SIMS measurement.

Then, the second layer 32 which is, for example, the n-junction layer, follows and is nominally doped only with Si.

As segregation of Te occurs on top of the first layer 33, the Te continues to be present in the second layer 32 but the Te concentration decays towards the active region 22. In the second layer 32, the concentration of Si may be higher than the concentration of Te, however, the Si concentration in the second layer 32 is lower than the Te concentration in the first layer 33. The Te concentration in the first layer 33 and the Si concentration in the second layer 32 are constant throughout these layers 32, 33 within manufacturing tolerances.

In the example shown, the second layer 32 is of AlInP and has a thickness of about 200 nm and a Si concentration of nominally 2×10¹⁸ cm⁻³. The Te decays from around 1×10¹⁸ cm⁻³ to around 7×10¹⁶ cm⁻³ across the second layer 32.

Optionally, there is the segregation layer 31 directly between the active region 22 and the second layer 32. The segregation layer 31 is nominally undoped or lowly doped. There are only minor traces of Si present in the segregation layer 31. The Te further decays from about 7×10¹⁶ cm⁻³ to around 5×10¹⁶ cm⁻³ across the segregation layer 31 so that at the beginning of the active region 22 there is only a quite minor Te concentration not disturbing the electroluminescence occurring in the active region 22. A thickness of the segregation layer 31 is in this example about 50 nm and includes a thin layer of AlInP, a thin composition ramp and a thin cladding of quantum barrier material, which are not distinguished due to scan resolution limitations.

Directly on the segregation layer 31, there is the active region 22 comprising the MQW structure and followed along the growth direction G by the p-side stack 21 which is made of AlInP, too.

Otherwise, the same as to FIGS. 1 to 3 may also apply to FIG. 4, and vice versa.

According to FIG. 4, the nominal doping concentrations of Si in the second layer 32 and of Te especially in the layers 33, 34, 37 are constant throughout the respective layer. In FIG. 5 it is shown that rampage doping can also be used for the second dopant, like Te. Thus, for example in the first layer 33 there can be an increase of the doping concentration C2 of the second dopant to a peak doping concentration C2p which may optionally be followed by a decay. According to FIG. 6, there is an interval doping of the second dopant. Interval and rampage doping may be combined with each other.

The concentration C2 in FIGS. 5 and 6 may be shown logarithmically or linearly.

The same applies analogously for the second layer 32 and the Si doping. Hence, the first dopant, like Si, can also be provided by using rampage doping or interval doping or any mixture thereof.

Otherwise, the same as to FIGS. 1 to 4 may also apply to FIGS. 5 and 6, and vice versa.

In FIG. 7, schematically a manufacturing method of the optoelectronic semiconductor device 1 is shown. In method step S1, the growth substrate 5 is provided and the layers 37, 35 and 34 may be grown. During this growth, the second one of the n-type dopants may be provided, like Te, especially only the second one of the n-type dopants.

In method step S2, the first layer 33 is grown. During growing the first layer 33, only the second one of the n-type dopants is provided, like Te. Hence, nominally there is no Si doping of the first layer 33.

Afterwards, in method step S3 the second layer 32 is grown directly on the first layer 33. During growth of the second layer 32, only the first one of the n-type dopants, like Si, is provided.

Then, in method step S4, the optional segregation layer 31 is grown without providing any n-type dopant, followed by growing the active region 22 and the p-side stack 23. Further optionally, method step S4 may include providing the carrier 4 and removing the growth substrate 5, and forming the at least one pixel as well as providing the roughening. Moreover, at least one passivation layer can be applied in this method step and electrical contacts may be applied, for example.

Otherwise, the same as to FIGS. 1 to 6 may also apply to FIG. 7, and vice versa.

In FIG. 8, a SIMS measurement of a modified semiconductor device 9 is illustrated. In this modified semiconductor device 9, there is no doping with the first one of the n-type dopants. Especially there is only Te doping in the n-side stack 21. Therefore, the segregation layer 31 needs to be much thicker and has in this example a thickness of around 300 nm to achieve the same low Te concentration of about 5×10¹⁶ cm⁻³ at the beginning of the active region 22.

Thus, compared with the embodiment of FIG. 4, in the modified semiconductor device 9 the segregation layer 31 needs to be significantly thicker.

In FIG. 9, a further example of the optoelectronic semiconductor device 1 is shown which is also configured for emitting visible light. In this case, the second layer 32 may directly adjoin the active region 22 or there may be a thin intermediate layer with a thickness of at most 20 nm or of at most 10 nm or of at most 5 nm or of at most 2 nm, for example. Further, the n-contact layer 35 is located between the first layer 33 configured as a current spreading layer and the roughening layer 34. In FIG. 9 it is further shown that the n-contact layer 35 can be of multi-layer fashion; this is also possible in all other examples of the optoelectronic semiconductor device 1.

Similar to FIG. 4, such a semiconductor layer sequence 2 may be used for devices with the general configuration of FIG. 2, for example.

Otherwise, the same as to FIGS. 1 to 8 may also apply to FIG. 9, and vice versa.

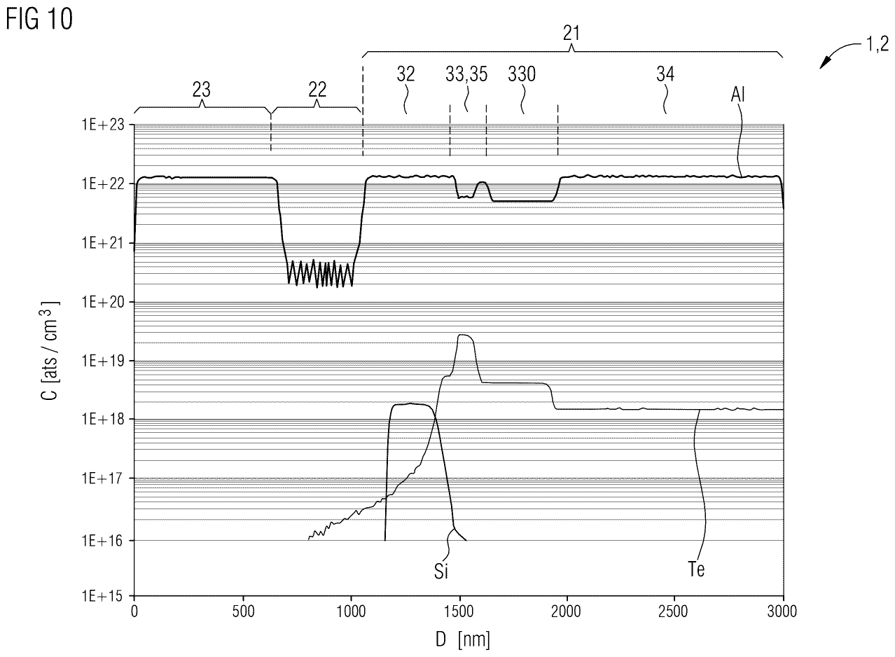

In the example of the optoelectronic semiconductor device 1 of FIG. 10 the n-contact layer 35 is the first layer directly between the first layer 33 and the further layer 330 which is the current spreading layer. The optoelectronic semiconductor device 1 of FIG. 10 is for emission of visible light, too.

Otherwise, the same as to FIGS. 1 to 9 may also apply to FIG. 10, and vice versa.

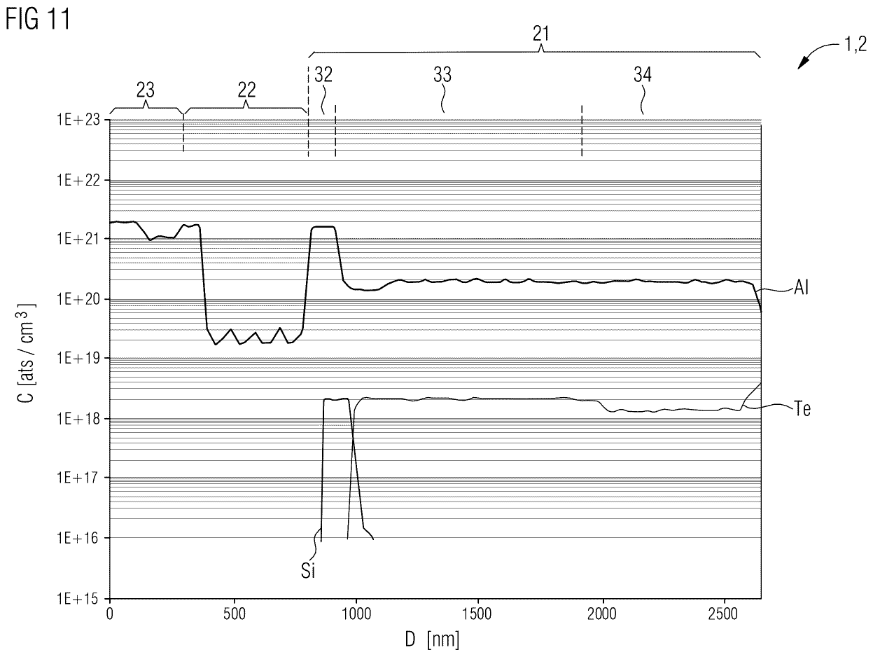

In FIG. 11, an optoelectronic semiconductor device 1 is shown which is configured for emitting near-IR radiation. Thus, the semiconductor layer sequence 2 is based on InAlGaAs. As in the InAlGaAs material system the Te concentration decays comparably fast, the second layer 32 being, for example, the n-junction layer, can be comparably thin. For example, a thickness of the second layer 32 is at least 50 nm and/or is at most 300 nm. In FIG. 11, the second layer 32 has a thickness of about 150 nm. Moreover, the second layer 32 can directly be at the active region 22 or there may be a thin intermediate layer with a thickness of at most 20 nm or of at most 10 nm or of at most 5 nm or of at most 2 nm, for example.

The first layer 33 can be the current spreading layer and may be comparably thick. For example, the thickness of the first layer 33 is at least 500 nm and/or is at most 2 μm. In FIG. 11, said thickness is about 1000 nm. Next to the first layer 33 there is the roughening layer 34. It is possible that there is no need for a dedicated n-contact layer. However, an n-contact layer and/or a segregation layer could also be present in IR devices analogous to visible light emitting optoelectronic semiconductor devices 1.

For example, a doping concentration of Si and Te, respectively, in the second layer 32 and in the first layer 33 is about the same and is constant within the manufacturing tolerances across the respective layer. For example, said doping concentration is 2×10¹⁸ cm⁻³.

Other than in visible light-emitting devices 1, at the second layer 32 the Al proportion may be increased.

Otherwise, the same as to FIGS. 1 to 10 may also apply to FIG. 11, and vice versa.

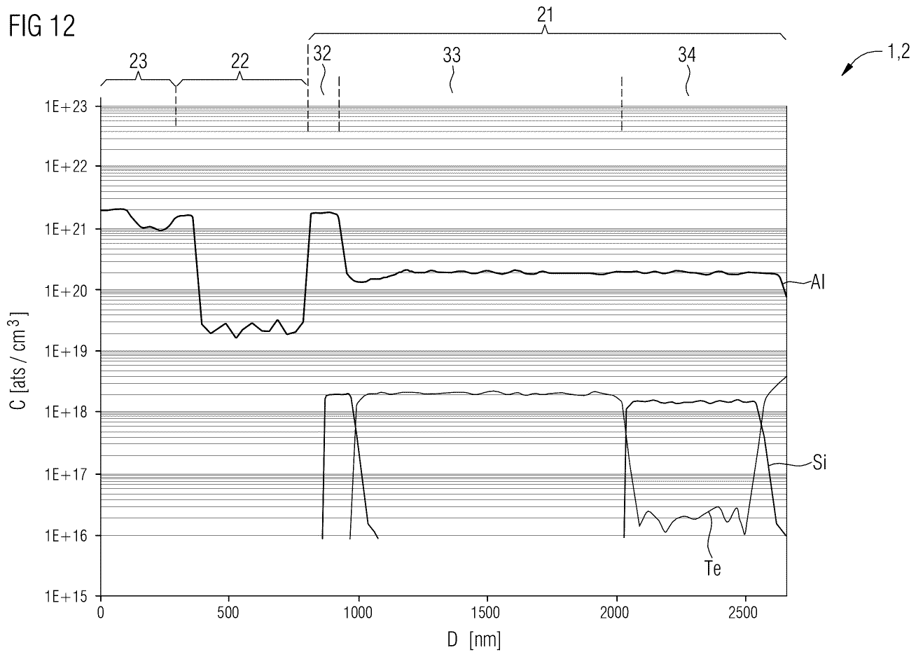

The optoelectronic semiconductor device 1 of FIG. 12 is also based on InAlGaAs for IR emission and is based on the example of FIG. 11. Other than in FIG. 11, according to FIG. 12 the roughening layer 34 is also doped with Si. Especially, the roughening layer 34 could be doped with both Si and Te. It is possible that the Si doping concentration exceeds the Te doping concentration, for example, by at least a factor of 10 and/or by at most a factor of 1000. In the example of FIG. 12, the Si doping concentration in the roughening layer 34 is 1.5×10¹⁸ cm⁻³ and the Te doping concentration is quite low at 2×10¹⁶ cm⁻³. The first layer 33 is only lowly doped with Te or free of Te which may mean that the Te concentration in the first layer is below 1×10¹⁶ cm⁻³ or below 5×10¹⁵ cm⁻³.

Otherwise, the same as to FIG. 11 may also apply to FIG. 12, and vice versa.

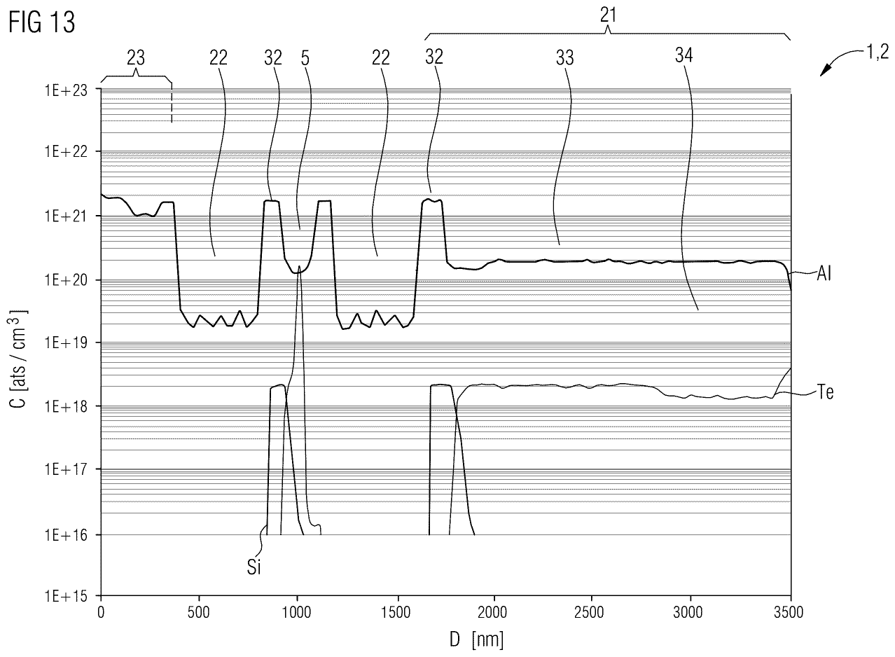

Finally, in FIG. 13 the IR-emitting optoelectronic semiconductor device 1 comprises a plurality of the active regions 22, for example, two of them. Between the active regions 22, there is a tunnel junction 5 and also one of the second layers 32. The second layer 32 between the active regions 22 may be thinner than the second layer 32 next to the first layer 33. In both second layers 32 the Te content may decay along the direction of growth so that both second layers 32 are intentionally doped during growth only with Si.

The tunnel junction 5 can also be doped with Te, especially only with Te; the Si in the tunnel junction 5 seen in FIG. 13 can be regarded an artifact of the SIMS measurement. For example, a peak doping concentration of Te in the tunnel junction 5 is at least 2×10¹⁹ cm⁻³ and/or at most 2×10²⁰ cm⁻³. For example, compare FIG. 13, said Te concentration is 1×10²⁰ cm⁻³.

If there are more than two of the active regions 22, between each pair of the active regions 22 there can be one of the thinner second layers 32 and one of the tunnel junctions 5.

Otherwise, the same as to FIGS. 11 and 12 may also apply to FIG. 13, and vice versa.

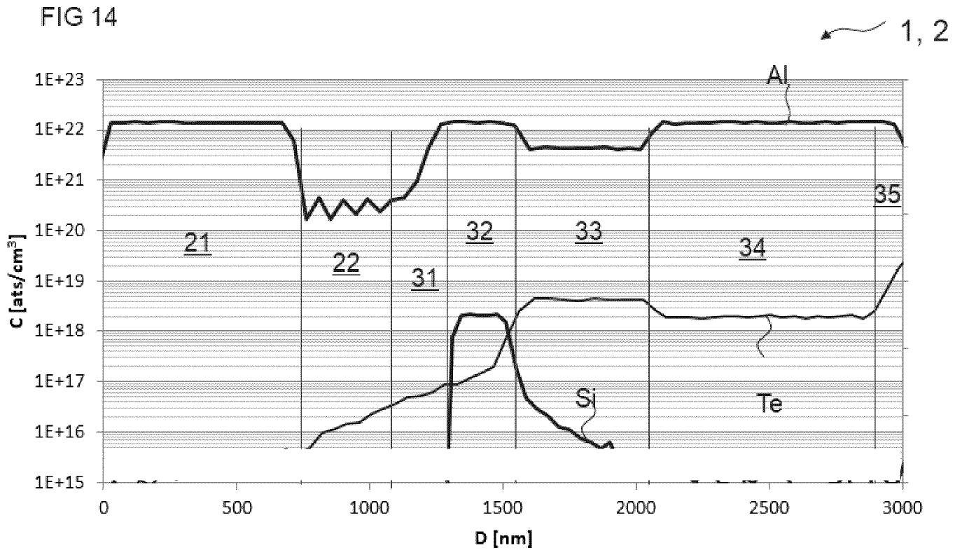

FIG. 14 essentially corresponds to the example of FIG. 14. However, the segregation layer 31 is indeed a layer stack and further includes a ramp concerning the Al content and an n setback layer between the active region 22 and said ramp. The n setback layer and the ramp are shown exaggerated in FIG. 14. For example, the ramp and the n setback layer have a thickness of at most 100 nm and of at least 10 nm or a thickness of at most 70 nm and of at least 20 nm and might therefore difficult to be distinguishable in a SIMS scan but might be visible with better depth resolution or in TEM rather than in SIMS.

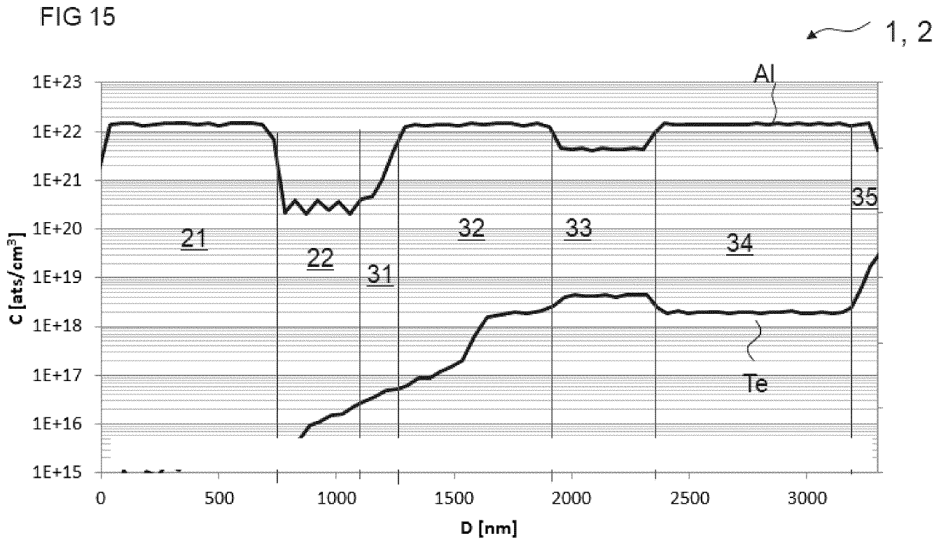

Analogously, FIG. 15 is based on FIG. 8, and the segregation layer 31 in this case also includes the ramp and/or the n setback layer. As in all other examples, optionally the n setback layer may be of a material the barrier layers between the quantum wells of the active region 22 are made of. For example, the n setback layer is a thicker barrier layer.

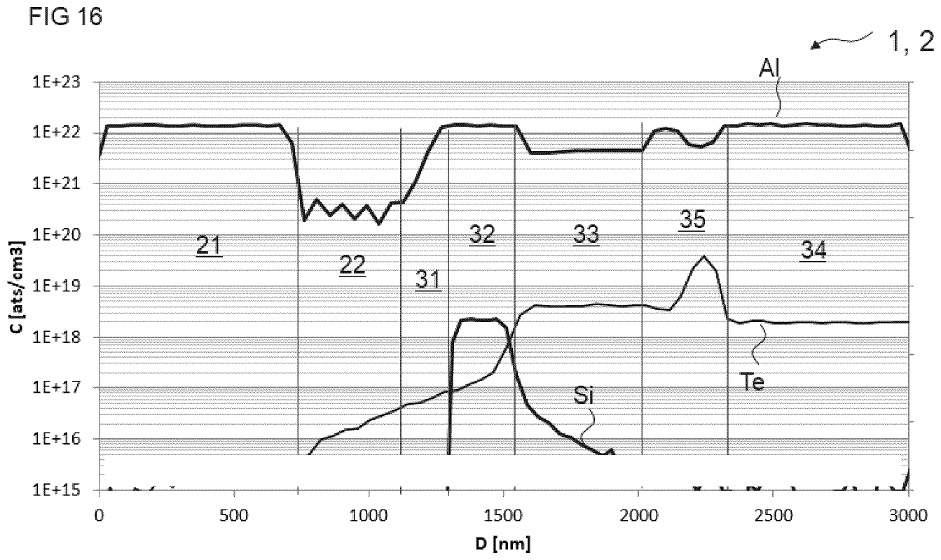

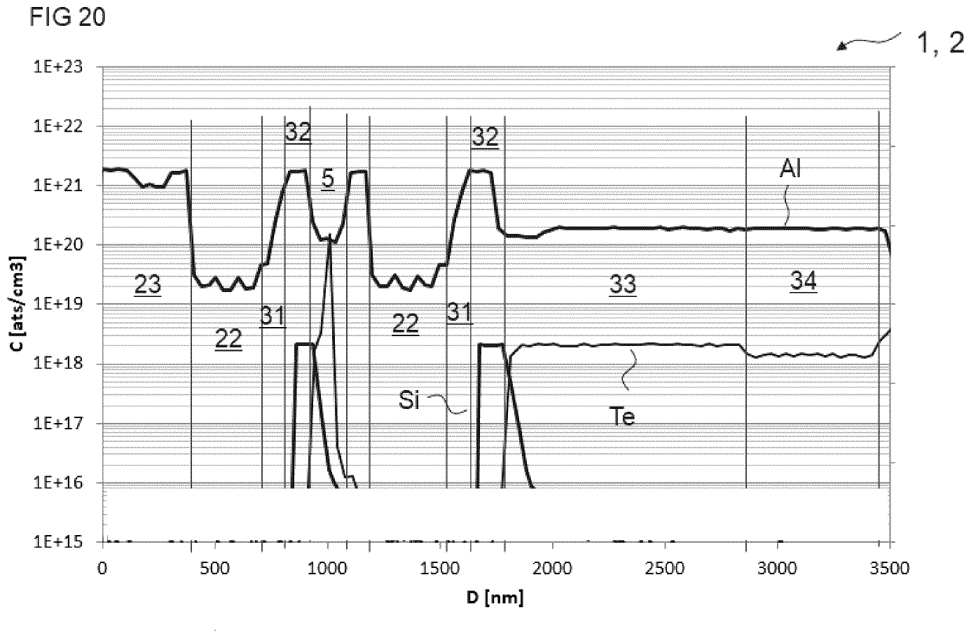

In the same manner, FIGS. 16 to 20 corresponds to FIGS. 9 to 13, respectively, but including in each case the segregation layer 31 as of, for example, FIG. 14 or FIG. 15. In case of FIG. 20, the segregation layer 31 can be present for each one of the active areas 22.

Otherwise, the same as to FIGS. 1 to 13 may also apply to FIGS. 14 to 20, and vice versa.

Thus, in the optoelectronic semiconductor devices 1 described herein there is a group VI doped first layer 33, doped with S, Se or Te, in the n-side layer stack which is typically either a contact layer or a current spreading layer stack. It is highly doped with >>5×10¹⁶ cm⁻³ but the doping concentration of this layer is at most 5×10¹⁹ cm⁻³ and it is not part of a tunnel junction 5 that one would use in LEDS with stacked active regions 22.

There could be other layers inside the n-side stack not explicitly listed above, like etch-stop layers, defect-blocking layers, metal-diffusion-suppression layers and/or cladding/spacer/buffer layers, like the Te-segregation layer 31. The same applies analogously for the p-side stack.

The n-junction layer, that is, the second layer 32, is mostly Si-doped in order to increase the distance of highly Te doped layers from the active region 22. In visible LEDs this is done in order to decrease the Te surface accumulation concentration before the active region 22. A background Te concentration can remain during to the dopant segregation decay; typically, the Te supply is shut off, but possibly one could even supply Te precursor with a very low concentration of at most 5×10¹⁶ cm⁻³ in order to prevent crystal ordering phenomena. In infrared LEDs this is done in order to separate diffusively mobile Te-induced crystal defects from the active region. Te doping with concentrations>>5×10¹⁶ cm⁻³ would typically only be used where it is really needed, namely in an n-current spreading layer and/or in an n-contact layer. Very small concentrations of Te of at most 5×10¹⁶ cm⁻³ could possibly be used to exploit surfactant properties during crystal growth.

The components shown in the figures follow, unless indicated otherwise, exemplarily in the specified sequence directly one on top of the other. Components which are not in contact in the figures are exemplarily spaced apart from one another. If lines are drawn parallel to one another, the corresponding surfaces may be oriented in parallel with one another. Likewise, unless indicated otherwise, the positions of the drawn components relative to one another are correctly reproduced in the figures.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

### LIST OF REFERENCE SIGNS

1 optoelectronic semiconductor device
2 semiconductor layer sequence
21 n-side stack
22 active region
23 p-side stack
31 segregation layer
32 second layer
33 first layer
330 further layer
34 roughening layer
35 n-contact layer
38 p-junction layer
39 p-contact layer
4 carrier
41 electric p-contact
411 electric p-through-contact
42 electric n-contact
421 electric n-through-contact
5 tunnel junction
6 mirror
9 modified semiconductor device
C concentration
C2 local concentration of the second one of the n-type dopants
C2p peak concentration of the second one of the n-type dopants
D depth
G growth direction
S method step

What is claimed is:

1. An optoelectronic semiconductor device comprising a semiconductor layer sequence which has an n-side stack, a p-side stack and an active region between the n-side stack and the p-side stack of a single or multi pn-junction, wherein
the n-side stack comprises a second layer containing two different n-type dopants, a first one of the n-type dopants has an atomic number of at most 14 and a second one of the n-type dopants is S, Se or Te,
the n-side stack further comprises a first layer being doped with the second one of the n-type dopants only or predominantly, and
the second layer is located between the active region and the first layer.

2. The optoelectronic semiconductor device according to claim 1,
AlInGaAsP material system,
region starts at a beginning of a first quantum structure that produces radiation in an intended use of the optoelectronic semiconductor device and at an intended emission wavelength of the optoelectronic semiconductor device, and
Te, and [symbol]
.

3. The optoelectronic semiconductor device according to claim 1,
the first layer is doped with the second one of the n-type dopants only so that a cumulative doping concentration of all other dopants together is at most 1×10¹⁷ cm⁻³ and/or the doping concentration of the second one of the n-type dopants exceeds said cumulative doping concentration by at least a factor of 10.

4. The optoelectronic semiconductor device according to claim 1,
n average or peak doping concentration of the first one of the n-type dopants in second layer is at least [symbol]
×10¹⁶ cm⁻³ and is at most 6×10¹⁸ cm⁻³.

5. The optoelectronic semiconductor device according to claim 4,
local doping concentration of the first one of the n-type dopants in the second layer is at least 0.7 times the peak doping concentration of the first one of the n-type dopants in the second layer.

6. The optoelectronic semiconductor device according to claim 1,
second layer is applied with an interval doping and/or a ramped doping.

7. The optoelectronic semiconductor device according to claim 1,
wherein a thickness of the second layer is at least 20 nm and is at most 1 μm.

8. The optoelectronic semiconductor device according to claim 1,
wherein a doping concentration of the second one of the n-type dopants decays by at least a factor of three over the second layer and towards the active region so that at the active region the doping concentration of the second one of the n-type dopants is at most 1×10¹⁸ cm⁻³.

9. The optoelectronic semiconductor device according to claim 1,
a peak doping concentration of the second one of the n-type dopants in the first layer is at least 1×10¹⁷ cm⁻³ and is at most 5×10¹⁹ cm⁻³.

10. The optoelectronic semiconductor device according to claim 1,
a thickness of the first layer is at least 25 nm and is at most 4 μm.

11. The optoelectronic semiconductor device according to claim 1,
first layer is at least 0.7 times the peak doping concentration of the first one of the n-type dopants in the first layer.

12. The optoelectronic semiconductor device according to claim 1,
wherein the n-side stack further comprises a segregation layer directly between the active region and the second layer,
wherein an average or maximum n-doping concentration in the segregation layer is at most 3×10¹⁷ cm⁻³.

13. The optoelectronic semiconductor device according to claim 12,
wherein an average or maximum doping concentration of the first one of the n-dopants is at most 1×10¹⁷ cm⁻³ and a maximum doping concentration of the second one of the n-type dopants is at least 3×10¹⁶ cm⁻³ and at most 1×10¹⁸ cm⁻³ in the segregation layer.

14. The optoelectronic semiconductor device according to claim 12,
wherein the segregation layer includes at least one of a ramp layer in which an Al content decreases towards the active region or a non-radiative pre-quantum well structure.

15. The optoelectronic semiconductor device according to claim 12,
5 nm and is at most 400 nm.

16. The optoelectronic semiconductor device according to claim 1,
compared with the first layer, the second layer has an increased Al proportion.

17. The optoelectronic semiconductor device according to claim 1,
first layer remote from the active region,
at least one of the first one or the second one of the n-type dopants only.

18. The optoelectronic semiconductor device according to claim 1,
which is a light-emitting diode for emitting incoherent radiation,

19. The optoelectronic semiconductor device according to claim 1,

[symbol]

20. A manufacturing method for producing an optoelectronic semiconductor device according to claim 1,
wherein producing the n-side stack of the semiconductor layer sequence includes the following steps:
growing the first layer and providing only or predominantly the second one of the n-type dopants during growth of the first layer, and
growing the second layer directly on the first layer and providing only or predominantly the first one of the n-type dopants during growth of the second layer.
